(19) United States
(12) Patent Application Publication
(10) Pub. No.: US 2025/0359051 A1
(43) Pub. Date: Nov. 20, 2025

(54) SEMICONDUCTOR DEVICE AND METHOD FOR FORMING THE SAME

(71) Applicant: YANGTZE MEMORY TECHNOLOGIES CO., LTD., Wuhan (CN)

(72) Inventors: Yating Shi, Wuhan (CN); Sai Zhang, Wuhan (CN); Xu Ji, Wuhan (CN); Shixuan Jin, Wuhan (CN)

(21) Appl. No.: 18/732,927

(22) Filed: Jun. 4, 2024

Related U.S. Application Data
(63) Continuation of application No. PCT/CN2024/093019, filed on May 14, 2024.

(51) Int. Cl. H10B 43/27

(52) U.S. Cl. CPC H10B 43/27

(57) ABSTRACT

Semiconductor devices and methods for forming the same are provided. In one example, a semiconductor structure includes a first conductor member extending laterally in a first direction; and a second conductor member extending in a second direction, perpendicular to the first direction, into the first conductor member. A first portion of the second conductor member is embedded in the first conductor member. In the first direction, a size of the first portion of the second conductor member embedded in the first conductor member is greater than a size of a second portion of the second conductor member outside the first conductor member.

### CROSS-REFERENCE TO RELATED APPLICATIONS

This application is a continuation of International Application No. PCT/CN2024/093019, filed on May 14, 2024, which is hereby incorporated by reference in its entirety.

### BACKGROUND

The present disclosure relates to semiconductor devices and fabrication methods thereof.

Planar memory cells are being scaled down by improving process technology, circuit design, programming algorithms, and fabrication techniques. However, as the feature sizes of the memory cells approach their lower limits, the planar process and fabrication techniques become increasingly challenging and costly. Consequently, the memory density of planar memory cells approaches an upper limit.

A three-dimensional (3D) memory architecture offers a solution to the density limitation in planar memory cells. The 3D memory architecture includes a memory array and peripheral devices for controlling signals to and from the memory array.

### SUMMARY

In one example, a semiconductor structure may include a first conductor member extending laterally in a first direction; and a second conductor member extending in a second direction, perpendicular to the first direction, into the first conductor member. A first portion of the second conductor member may be embedded in the first conductor member. In the first direction, a size of the first portion of the second conductor member embedded in the first conductor member may be greater than a size of a second portion of the second conductor member outside the first conductor member.

In some implementations, the first conductor member may include an undercut edge configured to receive the first portion of the second conductor member to be in the first conductor member.

In some implementations, the undercut edge may include a curve.

In some implementations, in the first direction, a difference between a furthest edge of the first portion of the second conductor member and a furthest edge of the second portion of the second conductor member may be greater than 0 and less than or equal to approximately 80 nm.

In some implementations, a ratio of a depth of the first portion of the second conductor member into the first conductor member to a thickness of the first conductor member, in the second direction, may be between 0.3 and 1.

In some implementations, a depth of the first portion of the second conductor member into the first conductor member may be equal to a thickness of the first conductor member, in the second direction.

In some implementations, in the second direction, a depth of the first portion of the second conductor member into the first conductor member may be between 20 nm and 35 nm.

In some implementations, a bottom surface of the first portion of the second conductor member may be flush with a bottom surface of the first conductor member.

In some implementations, a material of the first conductor member may be different from a material of the second conductor member.

In some implementations, the first conductor member may be a layer positioned in a plane defined by the first direction and a third direction perpendicular to the first direction. The second conductor member may be a connection structure extending in the second direction. The connection structure may be configured to have an electrical connection with the layer.

In another example, a memory device may include a memory array structure; a staircase structure adjacent to the memory array structure and comprising a plurality of stairs extending in a first direction; and a contact extending, in a second direction perpendicular to the first direction, through the staircase structure into a conductive layer of one stair of the plurality of stairs in the staircase structure. A first portion of the contact may be embedded in the conductive layer. In the first direction, a size of the first portion of the contact embedded in the conductive layer may be greater than a size of a second portion of the contact outside the conductive layer.

In some implementations, the conduct may include a glue layer in contact with the conductive layer; and a conductor layer surrounded by the glue layer and comprising one or more conductive materials.

In some implementations, the one or more conductive materials may include tungsten (W).

In some implementations, the glue layer may include titanium/titanium nitride (Ti/TiN) layers.

In some implementations, the conductive layer may include an undercut edge configured to receive the first portion of the contact in the conductive layer.

In some implementations, the undercut edge may include a curve.

In some implementations, in the first direction, a difference between a furthest edge of the first portion of the contact and a furthest edge of the second portion of the contact may be greater than 0 and less than or equal to approximately 80 nm.

In some implementations, a ratio of a depth of the first portion of the contact into the conductive layer to a thickness of the conductive layer, in the second direction, may be between 0.3 to 1.

In some implementations, a depth of the first portion of the contact into the conductive layer may be equal to a thickness of the conductive layer in the second direction.

In some implementations, in the second direction, a depth of the first portion of the contact into the conductive layer may be between about 20 nm and about 35 nm.

In some implementations, a bottom surface of the first portion of the contact may be flush with a bottom surface of the conductive layer.

In still another example, a method for forming a semiconductor device may include forming a first conductor member extending laterally in a first direction; and forming a second conductor member extending in a second direction, perpendicular to the first direction, into the first conductor member. A first portion of the second conductor member may be embedded in the first conductor member. In the first direction, a size of the first portion of the second conductor member embedded in the first conductor member may be greater than a size of a second portion of the second conductor member outside the first conductor member.

In some implementations, forming the second conductor member extending in the second direction, may include forming a first opening extending, in the second direction, through a semiconductor structure into the first conductor member, a bottom surface of the first opening comprising a first roughness; performing an isotropic etching on the bottom surface of the first opening to form a second opening having a lateral recess in the first conductor member; and forming the second conductor member in the second opening. A bottom surface of the second opening may include a second roughness, the second roughness being less than the first roughness. The lateral recess of the second opening may include an undercut edge in the first conductor member.

In some implementations, in the second direction, the bottom surface of the second opening may include peaks and valleys with respect to a mean value of the peaks and valleys. A difference between a highest peak and a lowest valley of the peaks and valleys may be less than 3 nm.

In some implementations, forming the second conductor member may include forming a first conductor layer over sidewalls and the bottom surface of the second opening; and forming a second conductor layer to fill the second opening.

In some implementations, performing the isotropic etching may include performing an isotropic etching, using an etchant, on the bottom surface of the first opening for a time.

In some implementations, the etchant comprises a mixture of a phosphoric acid (H₃PO₄), a nitric acid (HNO₃), an acetic acid (CH₃COOH), and a water (H₂O).

In some implementations, ratios of the phosphoric acid (H₃PO₄), the nitric acid (HNO₃), the acetic acid (CH₃COOH), and the water (H₂O) may be: H₃PO₄:HNO₃:CH₃COOH:H₂O=(0˜0.71]:(0˜0.005]:(0˜0.145]:(0˜0.12], where (value1˜value2] represents a value greater than value 1 and less than or equal to value2.

In some implementations, the ratios of the phosphoric acid (H₃PO₄), the nitric acid (HNO₃), the acetic acid (CH₃COOH), and the water (H₂O) may be: H₃PO₄:HNO₃:CH₃COOH: H₂O=0.71:0.005:0.145:0.12.

In some implementations, the time may be between 150 seconds and 500 seconds.

In some implementations, the undercut edge may include a curve.

In some implementations, a difference between a furthest edge of the first portion of the second conductor member and a furthest edge of the second portion of the second conductor member may be greater than 0 and less than or equal to approximately 80 nm.

In some implementations, a ratio of a depth of the lateral recess to a thickness of the first conductor member, in the second direction, may be between 0.3 and 1.

In some implementations, in the second direction, a depth of the first portion of the second conductor member into the first conductor member may be equal to a thickness of the first conductor member.

In some implementations, in the second direction, a depth of the first portion of the second conductor member into the first conductor member may be between 20 nm and 35 nm.

In some implementations, a bottom surface of the first portion of the second conductor member may be flush with a bottom surface of the first conductor member.

In some implementations, the semiconductor device may be a three-dimensional (3D) memory device. The semiconductor structure may be a staircase structure, and the second conductor member may be a contact extending, in the second direction, through the staircase structure. The method may further include before forming the contact, forming channel structures extending through a memory stack structure including interleaved conductive layers and dielectric layers. The first conductor member may include an extension of a conductive layer of the conductive layers in the memory stack structure.

In yet another example, a memory system is provided. The memory system may include a memory device and a memory controller coupled to the memory device and configured to control the memory device through a peripheral circuit. The memory device may be configured to store data and include a first semiconductor structure and a second semiconductor structure bonded with the first semiconductor structure and including the peripheral circuit configured to control an operation of the memory device through a contact and a conductive layer. The first semiconductor structure may include a memory array structure; a staircase structure adjacent to the memory array structure and including a plurality of stairs extending in a first direction; and a contact extending, in a second direction perpendicular to the first direction, through the staircase structure into the conductive layer of one stair of the plurality of stairs in the staircase structure. A first portion of the contact may be embedded in the conductive layer. In the first direction, a size of the first portion of the contact embedded in the conductive layer may be greater than a size of a second portion of the contact outside the conductive layer.

### BRIEF DESCRIPTION OF THE DRAWINGS

The accompanying drawings, which are incorporated herein and form part of the specification, illustrate some implementations of the present disclosure and, together with the description, further serve to explain the principles of the present disclosure and to enable a person skilled in the pertinent art to make and use the present disclosure.

FIG. 1A illustrates roughness present at the bottom surface of a contact opening created on a conductive layer.

FIG. 1B illustrates the resulting rough interface between the contact and the conductive layer based on FIG. 1A.

FIG. 2A illustrates an exemplary method for forming a 3D memory device having a contact, according to some aspects of the present disclosure.

FIG. 2B illustrates another exemplary method for bringing a connection between two conductor members in a memory device, according to some aspects of the present disclosure.

FIGS. 3A-3B illustrate an exemplary fabrication process for forming a contact of a 3D memory device, according to some aspects of the present disclosure.

FIG. 4A illustrates a cross-sectional view showing the roughness of the bottom surface of a contact opening.

FIG. 4B illustrates an enlarged view of the bottom surface of the contact in Box ‘A’ of FIG. 4A.

FIG. 5A illustrates an exemplary bottom surface profile of a contact opening, according to some aspects of the present disclosure.

FIG. 5B illustrates an enlarged view of the bottom surface of the contact opening in Box ‘B’ of FIG. 5A, according to some aspects of the present disclosure.

FIGS. 6A and 6B illustrate various exemplary bottom profiles of contact openings, according to some aspects of the present disclosure.

FIGS. 7A and 7B illustrate various exemplary connections between a contact structure and a conductive layer, according to some aspects of the present disclosure.

FIG. 8 illustrates an exemplary glue layer deposition process, according to some aspects of the present disclosure.

FIG. 9 illustrates an exemplary memory device having contacts, according to some aspects of the present disclosure.

FIGS. 10A and 10B illustrate various exemplary connections between two conductor members, according to some aspects of the present disclosure.

FIG. 11 illustrates a block diagram of an exemplary system having a 3D memory device, according to some aspects of the present disclosure.

FIG. 12A illustrates a diagram of an exemplary memory card having a 3D memory device, according to some aspects of the present disclosure.

FIG. 12B illustrates a diagram of an exemplary solid-state drive (SSD) having a 3D memory device, according to some aspects of the present disclosure.

Some implementations of the present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “some implementations,” “exemplary implementations,” “other implementations,” “some examples,” etc., indicate that the implementation described may include a particular feature, structure, or characteristic, but every implementation may not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to effect such feature, structure, or characteristic in connection with other implementations whether or not explicitly described.

In general, terminology may be understood at least in part from usage in context. For instance, the term “one or more” as used herein, depending at least in part upon context, may be used to describe any feature, structure, or characteristic in a singular sense or may be used to describe combinations of features, structures, or characteristics in a plural sense. Similarly, terms, such as “a,” “an,” or “the,” again, may be understood to convey a singular usage or to convey a plural usage, depending at least in part upon context. In addition, the terms “based on” and “according to” may be understood as not necessarily intended to convey an exclusive set of factors and may, instead, allow for the existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Furthermore, a layer can be a region of a homogeneous or inhomogeneous continuous structure that has a thickness less than the thickness of the continuous structure. For instance, a layer can be located between any pair of horizontal planes between, or at, a top surface and a bottom surface of the continuous structure. A layer can extend laterally, vertically, and/or along a tapered surface. A substrate can be a layer, can include one or more layers therein, and/or can have one or more layers thereupon, thereabove, and/or therebelow. A layer can include multiple layers. For instance, an interconnect layer can include one or more conductor and contact layers (in which interconnect lines and/or vertical interconnect access ‘VIA’ contacts are formed) and one or more dielectric layers.

As used herein, the terms “nominal/nominally” and “substantial/substantially” refer to a desired, or target, value of a characteristic or parameter for a component or a process operation, set during the design phase of a product or a process, together with a range of values above and/or below the desired value. The range of values can be due to slight variations in manufacturing processes or tolerances. As used herein, the terms “about” and “approximately” indicate the value of a given quantity that can vary based on a particular technology node associated with the subject semiconductor device. Based on the particular technology node, the terms “about” and “approximately” can indicate a value of a given quantity that varies within, for example, 10-30% of the value (e.g., +10%, +20%, or +30% of the value).

As used herein, the term “3D memory device” may refer to a semiconductor device with vertically oriented strings of memory cell transistors (referred to herein as “memory strings,” such as NAND memory strings) on a laterally-oriented substrate so that the memory strings extend in the vertical direction with respect to the substrate. As used herein, the term “vertical/vertically” means nominally perpendicular to the lateral surface of a substrate.

In a three-dimensional (3D) memory device, data-storage memory cells can be arranged in the form of memory strings, extending vertically through a memory stack structure in a stack structure. A staircase stack structure, serving various functions such as a foundation for word line fan-out, may also be included in the stack structure of a 3D memory device and can be formed in the vicinity of the memory stack. The staircase stack structure can include multiple stairs, each arranged at a different depth within the staircase stack structure.

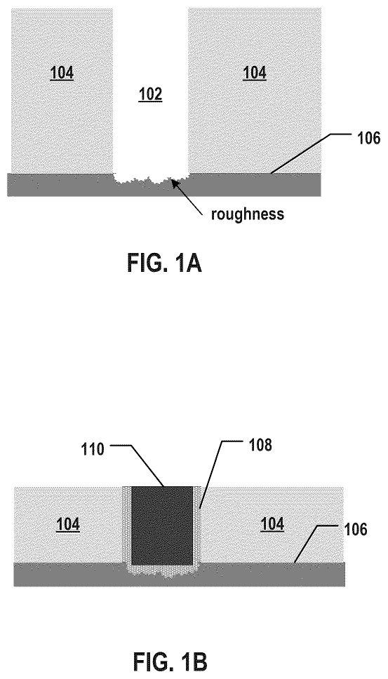

With the demand for larger storage capacity, the number of vertical levels within the memory stack structure may also increase. As a consequence, it has become more challenging to form contacts with greater vertical depths toward the stairs of the staircase stack structure. In the fabrication processes, as shown in FIG. 1A, a contact may be formed by initially creating a contact opening 102 extending through a staircase stack structure 104 into a conductive layer 106, extending from a memory stack. With the increasing number of vertical levels within the memory stack structure, the aspect ratio of the contact (e.g., the depth of the contact to its width) may also increase. As a result, the contact etching power is required to increase as well to create deeper contact openings. However, the increasing etching power can result in the roughness present at the bottom surface of contact opening 102, as shown in FIG. 1A.

Subsequently, to form a contact, one or more contact materials may then be filled into contact opening 102. For instance, as shown in FIG. 1B, a first contact layer 108 may be deposited over the sidewalls and bottom surface of contact opening 102. The roughness surface present at the bottom surface of contact opening 102, however, may further create a rough interface between conductive layer 106 and first contact layer 108. As a result, when subsequently forming a second contact layer 110 to fill contact opening 102, it may grow abnormally, potentially causing an abnormal contact resistance issue.

To address the aforementioned issues and others, the present disclosure proposes some solutions. In one solution, isotropic etching may be introduced to eliminate the roughness present at the bottom of contact opening 102 before the formation of the contact materials. With isotropic etching, the etch rates can be approximately equal in all orientations. Consequently, the rough surface at the bottom of contact opening 102 in FIG. 1A can be substantially smoothed, facilitating the subsequent formation of the contact. This proposed solution enhances the interface quality, improving the continuity at the interface for the contact material growth. As a consequence, the contact resistance can be accordingly reduced.

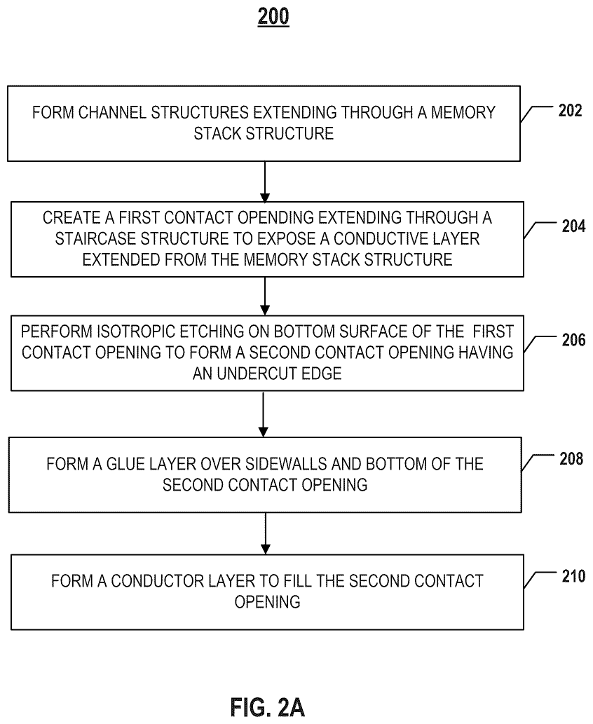

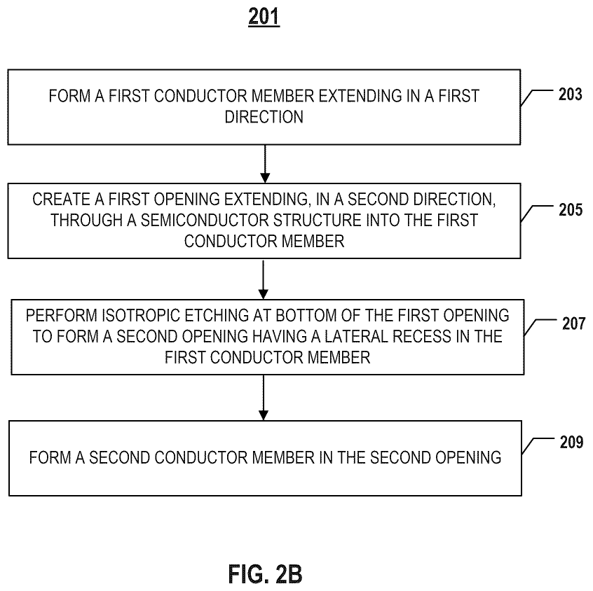

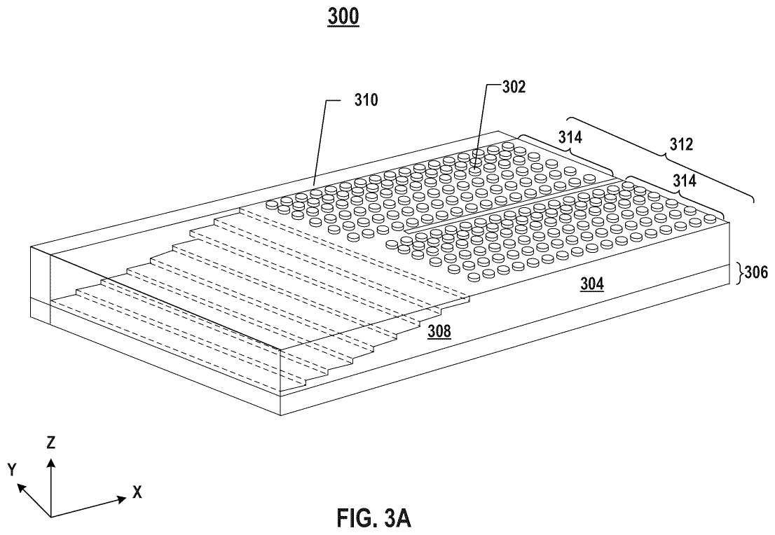

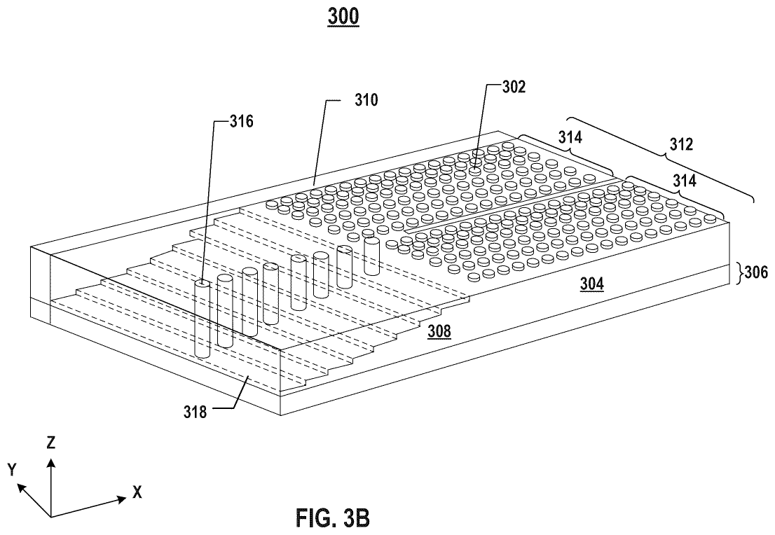

FIG. 2A illustrates an exemplary method 200 for forming a 3D memory device having a contact, according to some aspects of the present disclosure. FIGS. 3A-3B illustrate an exemplary fabrication process for forming a contact of a 3D memory device 300, according to some aspects of the present disclosure. In the following, details of method 200 will be described with reference to FIGS. 3A-3B. It is understood that the operations shown in method 200 in FIG. 2A are not exhaustive and other operations can be performed as well before, after, or between any of the illustrated operations.

Method 200 may start at operation 202. At operation 202, as shown in FIG. 3A, channel structures 302, vertically extending through a memory stack structure 304, may be formed.

To form channel structures 302 that extend through memory stack structure 304, an initial stack structure can be formed on a substrate 306. The initial stack structure can include vertically interleaved first dielectric layers and second dielectric layers. In some implementations, each first dielectric layer may include a layer of silicon oxide, while each second dielectric layer may include a layer of silicon nitride. The second dielectric layers can be sacrificial layers and replaced with conductive layers in a subsequent gate replacement process. The initial stack structure can be formed by one or more thin film deposition processes including, but not limited to, chemical vapor deposition (CVD), physical vapor deposition (PVD), atomic layer deposition (ALD), or any combination thereof. The first dielectric layers and the second dielectric layers can alternate in the vertical direction (the z-direction in FIG. 3A). The initial stack structure can include a plurality of layer pairs stacked vertically in the z-direction, each of which includes a first dielectric layer and a second dielectric layer. The number of layer pairs in the initial stack structure can determine the number of memory cells in 3D memory device 300.

In some implementations, substrate 306 may include silicon (e.g., single crystalline silicon), silicon germanium (SiGe), gallium arsenide (GaAs), germanium (Ge), silicon on insulator (SOI), or any other suitable materials. In some examples, substrate 306 may include single crystalline silicon, which is part of the wafer on which a 3D memory device is fabricated, either in its native thickness or being thinned.

It is noted that x, y, and z axes are included in FIG. 3A to further illustrate the spatial relationship of the components in 3D memory device 300. Substrate 306 of 3D memory device 300 includes two lateral surfaces extending laterally in the x-y plane: a top surface on the front side of the wafer on which substrate 306 can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of 3D memory device 300 is determined relative to substrate 306 of 3D memory device 300 in the z-direction (the vertical direction perpendicular to the x-y plane) when substrate 306 is positioned in the lowest plane of 3D memory device 300 in the z-direction. The same notion for describing the spatial relationship may be applied throughout the present disclosure.

The initial stack structure can include a first portion and a second portion. The first portion of the initial stack structure can be subsequently transformed into memory stack structure 304 corresponding to a core array region, while the second portion can be converted to a staircase stack structure 308 corresponding to a staircase region. Subsequently, a plurality of channel openings can be formed in the first portion of the initial stack structure, such that each channel opening can become the location for growing an individual channel structure 302. Each channel opening can extend vertically through the first portion of the initial stack structure. In some implementations, the fabrication processes for forming the channel openings may include wet etching and/or dry etching, such as deep-ion reactive etching (DRIE).

Channel structures 302 can then be formed in the first portion of the initial stack structure. For each channel opening, a memory layer (including a blocking layer, a storage layer, and a tunneling layer) and a channel layer are sequentially formed in this order along the sidewalls and the bottom surface of the channel opening. In some implementations, the memory layer can first be deposited along the sidewalls and bottom surface of the channel opening, and the semiconductor channel may then be deposited over the memory layer. The blocking layer, storage layer, and tunneling layer can be subsequently deposited in this order using one or more thin film deposition processes, such as ALD, CVD, PVD, any other suitable processes, or any combination thereof, to form the memory layer. The channel layer can then be formed by depositing a semiconductor material, such as polysilicon, over the tunneling layer of the memory layer using one or more thin film deposition processes, such as ALD, CVD, PVD, any other suitable processes, or any combination thereof. In some implementations, a first silicon oxide layer, a silicon nitride layer, a second silicon oxide layer, and a polysilicon layer (a.k.a., a “SONO” structure) are subsequently deposited to form the memory layer and the channel layer of channel structure 302.

As shown in FIG. 3A, a staircase stack structure 308 can be formed at the edge or vicinity of memory stack structure 304. In some implementations, staircase stack structure 308 can be formed by performing a plurality of trim-etch cycles for the initial stack structure toward substrate 306. Edges of the first/second dielectric layer pairs in the initial stack structure along the vertical direction (i.e., the z-direction in FIG. 3A) away from substrate 306 can be staggered laterally toward substrate 306. To form a staircase stack structure, a photoresist layer can be patterned to expose portions of the top one of the first/second dielectric layer pairs. The patterned photoresist layer can be used as an etch mask to etch the exposed portions of the top one of the layer pairs by wet etching and/or dry etching. Any suitable etchants (e.g., wet etching and/or dry etching) can be used to remove the entire thickness of the top one of the first/second dielectric layer pairs in the exposed portions (including the first dielectric layers and the second dielectric layers therein). The etched thickness can be controlled by etch-stop at different materials (e.g., silicon nitride and silicon oxide) used in the layer pair. The etching of the exposed portions of the top one of the layer pairs can result in the exposure of portions of the one beneath the top one of the layer pairs.

Subsequently, a slit opening extending through the initial stack structure until/into substrate 306 can be formed. In some implementations, the slit opening can be a continuous slit across the first portion and the second portion of the initial stack structure, in the x-direction. In some implementations, the fabrication processes for forming the slit opening may include wet etching and/or dry etching, such as DRIE, of the first dielectric layers and the second dielectric layers. The etching processes through the initial stack structure may not stop at the top surface of substrate 306 and may continue to etch part of substrate 306 to ensure that the slit opening extends vertically all the way through the first dielectric layers and the second dielectric layers of the initial stack structure.

Through the slit opening, the gate replacement process may be performed to replace the second dielectric layers of the initial stack structure with the conductive layers. In some implementations, each second dielectric layer can be replaced by a conductive layer, thereby forming a plurality of conductor/dielectric layer pairs as memory stack structure 304 in the first region (i.e., the core array region of 3D memory device 300). The replacement of the second dielectric layers with the conductive layers can be performed, through the slit opening, by wet etching and/or dry etching of the second dielectric layers selective to the first dielectric layers and filling the slit opening with the conductive layers. In some examples, the conductive layers in memory stack structure 304 can serve as gate lines and word lines for channel structures 302.

The conductive layers can be formed by thin film deposition processes, such as CVD, ALD, any other suitable process, or any combination thereof. In some implementations, the conductive layers can include one or more conductive materials including, but not limited to, tungsten (W), cobalt (Co), copper (Cu), aluminum (Al), titanium nitride (TiN), polycrystalline silicon (polysilicon), doped silicon, silicides, or any combination thereof. In some implementations, the conductive layers can include tungsten (W), the first dielectric layers can include silicon oxide, and the second dielectric layers (as the sacrificial layers) can include silicon nitride.

A slit structure 310 can be formed based on the slit opening, according to some implementations. In some implementations, the slit opening can be filled with a slit spacer that separates, in the y-direction, the conductive layers in memory stack structure 304 and staircase stack structure 308 between different memory blocks 312. In some implementations, when 3D memory device 300 is a NAND Flash memory device, each memory block 312 may be the smallest erasable unit of the NAND Flash memory device. In some implementations, slit structure 310 may be an insulating structure. In other words, slit structure 310 may not include any contact (e.g., a source contact) and thus, does not introduce parasitic capacitance and leakage current with the conductive layers. In some implementations, slit structure 310 may include a front-side source contact which may further include one or more conductive materials (e.g., W, polysilicon, and/or TiN) circumscribed by the slit spacer. In some implementations, each memory block 312 can be divided into multiple memory fingers 314, as shown in FIG. 3A, by further inserting another insulating structure within memory block 312.

As a consequence, channel structures 302 can each extend vertically through memory stack structure 304 including interleaved first dielectric layers and conductive layers, and staircase stack structure 308 can be formed at the edge/vicinity of memory stack structure 304, as shown in FIG. 3A.

Returning to FIG. 2A, method 200 may proceed to operation 204. At operation 204, a plurality of contact openings 316 can be formed, vertically extending through staircase stack structure 308. In some implementations, contact openings 316 can be formed to extend, in the z-direction, through staircase stack structure 308 at different depths, as shown in FIG. 3B. The edges of the conductor/dielectric layer pairs in staircase stack structure 308 along the vertical direction away from substrate 306 can be staggered laterally toward channel structures 302. In some implementations, each contact opening 316 can penetrate staircase stack structure 308 until a corresponding conductive layer 318 of staircase stack structure 308 is exposed.

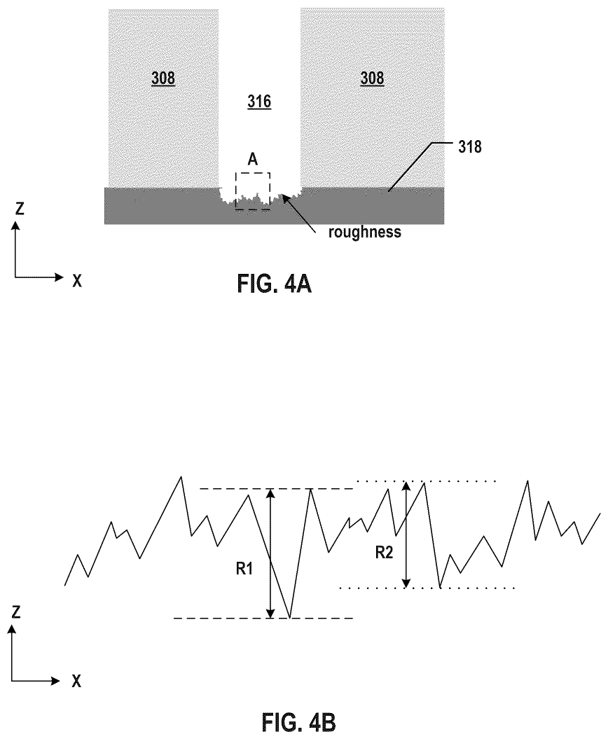

FIG. 4A illustrates a cross-sectional view showing the rough bottom surface of contact opening 316, while FIG. 4B illustrates an enlarged view of the bottom surface of contact opening 316 in Box ‘A’ of FIG. 4A. As shown in FIG. 4A, when contact opening 316 is created at operation 204, the bottom surface of contact opening 316 can be rough or have a roughness.

In the present disclosure, as used herein, the terms “rough” and “roughness” may be used to describe a surface that is uneven and coarse, having variations in height (in the z-direction) across its surface, as shown in FIG. 4B. To quantify “roughness,” a roughness threshold can be established. In certain instances, when the height difference between adjacent peaks and valleys (i.e., a peak/valley pair) exceeds the roughness threshold, and there are two or more peak/valley pairs (e.g., sets R1 and R2 in FIG. 4B) meeting this criterion, the surface can be classified as “rough.” In some examples, the roughness threshold can be set at 3 nanometers (nm). It is apparent that the methodology provided above serves as an exemplary approach to defining roughness, but there are alternative methods available for achieving similar objectives as well.

The roughness surface present at the bottom surface of contact opening 316, however, may further create a rough interface between a contact structure formed later, potentially causing an abnormal contact resistance issue. To enhance the interface quality, the continuity at the bottom surface of contact opening 316 may need to be improved for contact material growth.

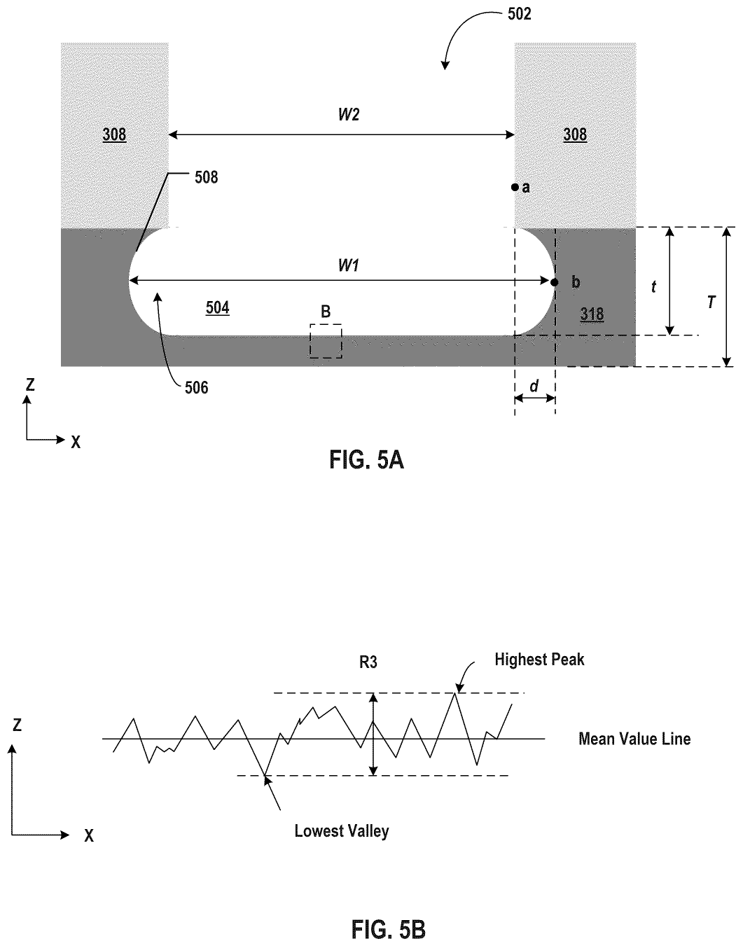

Method 200 in FIG. 2A may proceed to operation 206, in which an isotropic etching may be performed, according to some implementations. FIG. 5A illustrates an exemplary bottom surface profile of a contact opening, according to some aspects of the present disclosure. FIG. 5B illustrates an enlarged view of the bottom surface of the contact opening in Box ‘B’ of FIG. 5A, according to some aspects of the present disclosure.

In some implementations, the isotropic etching may be performed to further remove part of conductive layer 318 of staircase stack structure 308, thereby expanding contact opening 316 into another contact opening 502 in its size. In some implementations, contact opening 502 may include a lateral recess 504 formed within conductive layer 318, as shown in FIG. 5A. Lateral recess 504 can extend laterally (e.g., in all lateral orientations on the x-y plane) to include an undercut edge 506 inside conductive layer 318, according to some implementations.

In some implementations, the isotropic etching can include wet etching and/or dry etching using an etchant. The etchant may include a chemical mixture of phosphoric acid (H₃PO₄), nitric acid (HNO₃), acetic acid (CH₃COOH), and water (H₂O), according to some implementations. Water can be a solvent. In some implementations, the ratios of the phosphoric acid (H₃PO₄), the nitric acid (HNO₃), the acetic acid (CH₃COOH), and the water (H₂O) can be formulated as follows:

H₃PO₄:HNO₃:CH₃COOH:H₂O=(0˜0.71]:(0˜0.005]:(0˜0.145]:(0˜0.12] (1).

In some examples, the ratios in formula (1) can include volume ratios of the phosphoric acid (H₃PO₄), the nitric acid (HNO₃), the acetic acid (CH₃COOH), and the water (H₂O). The notation (0˜value2] in formula (1) is used to represent that the amount of a specific component can be greater than 0 and less than or equal to ‘value2.’ For instance, (0˜0.71] in formula (1) can represent a value greater than 0 and less than or equal to 0.71. In some examples, the ratios can be:

H₃PO₄:HNO₃:CH₃COOH:H₂O=0.71:0.005:0.145:0.12 (2).

In some implementations, the etched amounts may be controlled by managing the etching time so as to substantially remove uneven and rough surfaces to a desired level. In some implementations, based on the recipe of the etchant according to formula (2), the etching time may be at a hundred-second level. In some examples, the time can be in the range of 150 seconds to 500 seconds.

As used herein, the term “isotropic etching” can be used to refer to an etching process in which a material is removed uniformly in all directions. Unlike anisotropic etching, an isotropic etching is characterized by its non-directional nature, meaning that an isotropic etching does not exhibit preferential removal along specific planes or orientations. As described above, the isotropic etching property leads to the removal of conductive layer 318 in all directions and can create an undercut edge 506 (shown in FIG. 5A) of conductive layer 318, leading to the formation of a recessed region beneath conductive layer 318. As a result, a rounded profile 508 with a degree of curvature and an undercut length can be obtained. In some implementations, the degree of curvature can be greater than 0 and less than or equal to approximately 180 degrees.

In the x-direction, an edge ‘a’ of lateral recess 504 (or undercut edge 506) can be observed, while an edge ‘b’ of the part of contact opening 502 outside lateral recess 504 can be observed, as shown in FIG. 5A. In some examples, edge ‘a’ can be a point on the sidewalls of contact opening 502, other than lateral recess 504, which has the maximum distance from the center line of contact opening 502. On the other hand, edge ‘b’ can be another point on the sidewalls of lateral recess 504 having the maximum distance from the center line of contact opening 502. Namely, edge ‘a’ can be the furthest edge of part of contact opening 502, other than lateral recess 504, and edge ‘b’ can be the furthest edge of lateral recess 504. In some instances, a difference d between edge ‘a’ and edge ‘b’ can be greater than 0 and less than or equal to about 80 nm. In some examples, distance d can be approximately less than or equal to about 66 nm.

In the isotropic etching, the bottom part of conductive layer 318 in lateral recess 504 can be further removed, such that lateral recess 504 can include undercut edge 506 in conductive layer 318 with, in the z-direction, a gouging depth t, as shown in FIG. 5A. With undercut edge 506, in the x-direction, the size (e.g., the width) of lateral recess 504 can be greater than the size (e.g., the width) of contact opening 502, other than lateral recess 504, outside lateral recess 504. In some instances, in view of the cross-sectional view shown in FIG. 5A, the width W₁ of lateral recess 504 can be greater than the width W₂ of contact opening 502. According to some implementations, undercut edge 506 can be configured to receive contact material(s) formed later. Thereby, part of the contact material(s) can be arranged/embedded in conductive layer 318.

In some implementations, gouging depth t can be in the range of 20 nm to 35 nm. In terms of the thickness T of conductive layer 318, a ratio of gouging depth t to the thickness T of conductive layer 318 can be in the range of 0.3 to 1. Compared to distance d between edge ‘a’ and edge “b,” a ratio of distance d to gouging depth t can be [0˜3.3], according to some implementations.

As the isotropic etching is performed, the bottom roughness of contact opening 502 can be reduced/eliminated and thus create a new bottom surface having less roughness or being smoother. After the isotropic etching is performed, the bottom surface of the new contact opening may include the second roughness, and the second roughness can be less than the first roughness of the bottom surface of contact opening 502. Namely, the second bottom surface of the new contact opening can be smoother than the first bottom surface of contact opening 502. The second roughness of the new contact opening may be determined using different methodologies. In some examples, the bottom surface of the new contact opening may include peaks and valleys with respect to a mean value of the peak and valleys, and thus, a second roughness R₃ of the new contact opening can be determined by the difference between the highest peak and the lowest valley of the peaks and valleys. In some examples, the second roughness can be less than 3 nm.

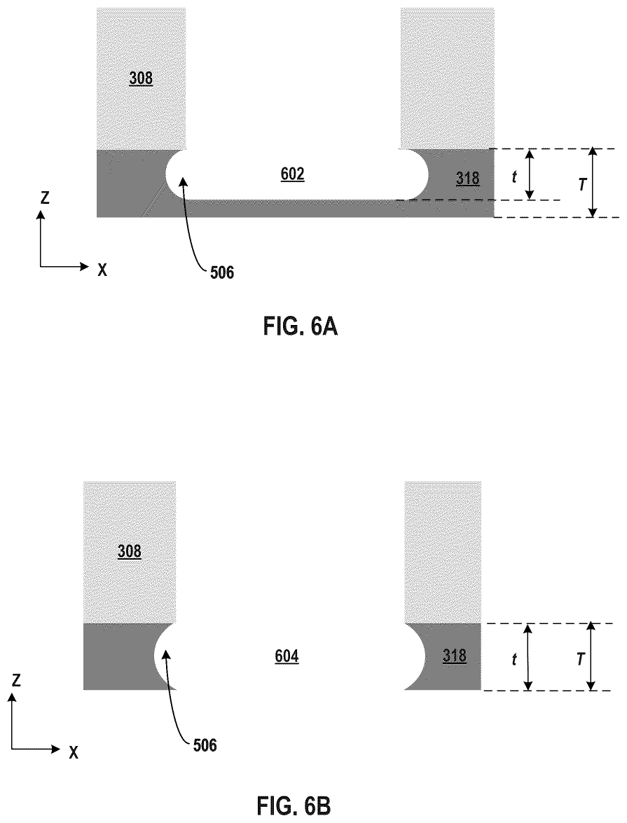

FIGS. 6A and 6B illustrate various exemplary bottom profiles of contact openings, according to some aspects of the present disclosure. In some implementations, an initial contact opening may be created. Subsequently, the isotropic etching can be performed for the first period of time, such that the roughness at the bottom surface of the initial contact opening can be reduced, and a lateral recess 602 in a new contact opening can be formed, as shown in FIG. 6A. The ratio of gouging depth t to the thickness T of conductive layer 318 can be less than 1. Namely, gouging depth t can be less than thickness T. As such, conductive layer 318 may still remain at the bottom of lateral recess 602 after the isotropic etching, as shown in FIG. 6A.

In other examples, the isotropic etching can be performed for the second period of time longer than the first period of time. As a consequence, a lateral recess 604, as shown in FIG. 6B, can be formed by isotopically removing the part of conductive layer 318 until a dielectric material (e.g., a dielectric layer) below conductive layer 318 is exposed. In some examples, lateral recess 604 can be of a larger size than lateral recess 602, both in the x-direction and the z-direction. According to FIG. 6B, the ratio of gouging depth t to the thickness T of conductive layer 318 can be approximately 1. Namely, gouging depth t can be equal to thickness T. That is, the bottom surface of lateral recess 604 (i.e., the bottom of the new contact opening) may be flush with the bottom surface of conductive layer 318. In the present disclosure, once undercut edge 506 is formed after the isotropic etching (i.e., whether gouging depth t is less than or equal to thickness T, the present disclosure does not limit thereto.

Returning to FIG. 2A, method 200 may proceed to operation 208. At operation 208, a glue layer may be formed over the sidewalls and bottom of the new contact opening, and a conductor layer can then be formed to fill the new contact opening at operation 210. Through the fabrication processes, the glue layer can be arranged and sandwiched between the conductor layer and conductive layer 318 in the lateral recess.

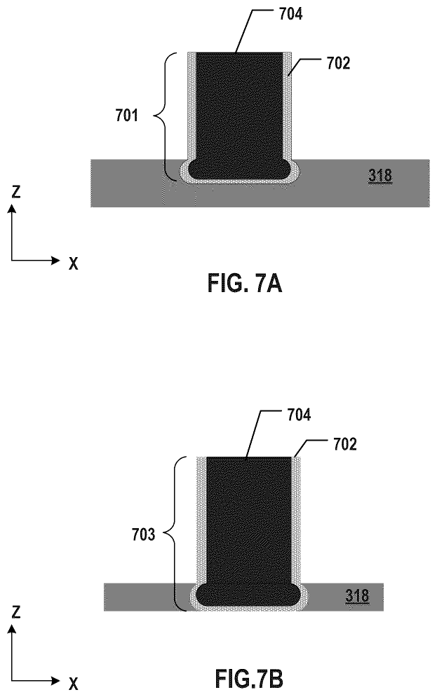

FIGS. 7A and 7B illustrate various exemplary connections between a contact and a conductive layer, according to some aspects of the present disclosure. FIG. 7A shows an exemplary connection between a contact structure 701 and conductive layer 318 based on the contact opening shown in FIG. 6A. As shown in FIG. 7A, as gouging depth t is less than thickness T of conductive layer 318, conductive layer 318 can remain below the contact opening in the z-direction. A glue layer 702 may be formed over the sidewalls and bottom of the new contact opening, and a conductor layer 704 can then be formed to fill the new contact opening. As a consequence, glue layer 702 as formed may surround conductor layer 704 in contact structure 701.

In some implementations, glue layer 702 and conductor layer 704 can be formed in undercut edge 506 in FIG. 5A, such that part of contact structure 701 as formed can be embedded into conductive layer 318. Through the fabrication processes, glue layer 702 can be arranged and sandwiched between conductor layer 704 and conductive layer 318. As a result, a mechanical and electrical connection between contact structure 701 and conductive layer 318 can be achieved. In some implementations, conductor layer 704 may include one or more conductive materials, e.g., tungsten (W), while glue layer 702 may include Ti/TiN layers.

On the other hand, FIG. 7B shows another exemplary connection between another contact structure 703 and conductive layer 318 based on the contact opening shown in FIG. 6B. As shown in FIG. 7B, as gouging depth t is equal to thickness T of conductive layer 318, conductive layer 318 can be all removed at the bottom of contact structure 703 in the z-direction. As a consequence, the bottom surface of contact structure 703 can be flush with the bottom surface of conductive layer 318, as shown in FIG. 7B.

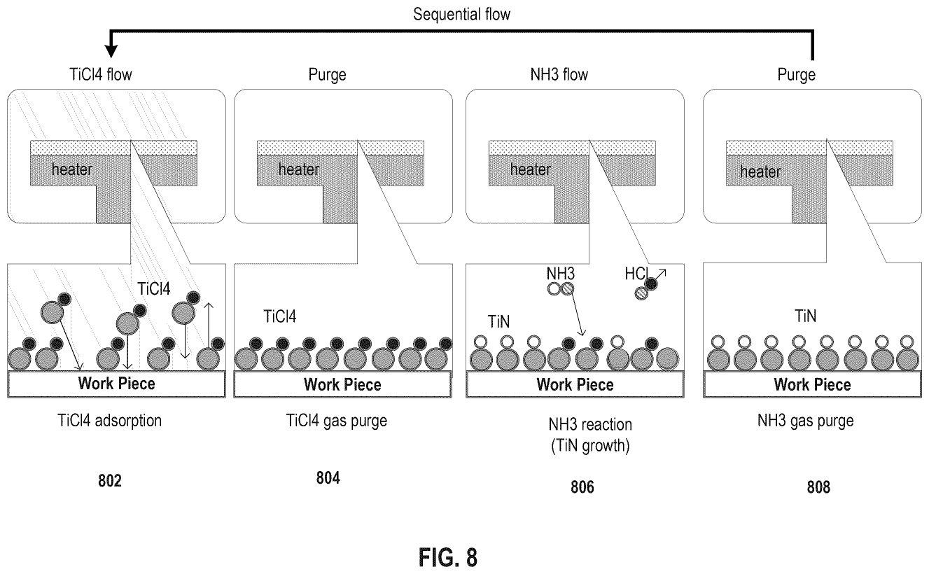

FIG. 8 illustrates an exemplary glue layer deposition process, according to some aspects of the present disclosure. As shown in FIG. 8, titanium tetrachloride (TiCl₄) can be used as the precursor, and ammonia (NH₃) can be used as an ammonia source. The precursor and the ammonia source are not limited to these materials. For instance, the precursor may be TaCl₅, TaF₅, TaBr₅, TiCl₄, TiBr₄, Til₄, or TiF₄, and the ammonia source may be NH₃, N₂H₄, N₂H₂, or other suitable ammonia gas. The present disclosure does not limit thereto.

In the present disclosure, as shown in FIG. 8, a wafer may be placed on a heater in the reaction chamber. The heater can be used to heat and maintain the temperature of the wafer to a preset process temperature. In FIG. 8, TiCl₄ absorption operation 802 may include high flow TiCl₄ operation and a purge operation 804. During the TiCl₄ absorption operation 802, a high flow TiCl₄ can be provided in the reaction chamber, and TiCl₄ can be absorbed or deposited on the wafer. During the nitridation operation, NH₃ can be provided in the reaction chamber. Nitridation operation, including ammonia treatments 806 and a purge operation 808, utilizes the NH₃ flow of multiple pulse-type nitridation operations to react with TiCl₄. The multiple pulse-type nitridation operations may include repeating high NH₃ pressure and short process time ammonia treatments followed by purge operation 808. TiCl₄ absorption operation 802 and pulse-type nitridation operations may be repeated several times until a sufficient thickness of glue layer 702 is formed.

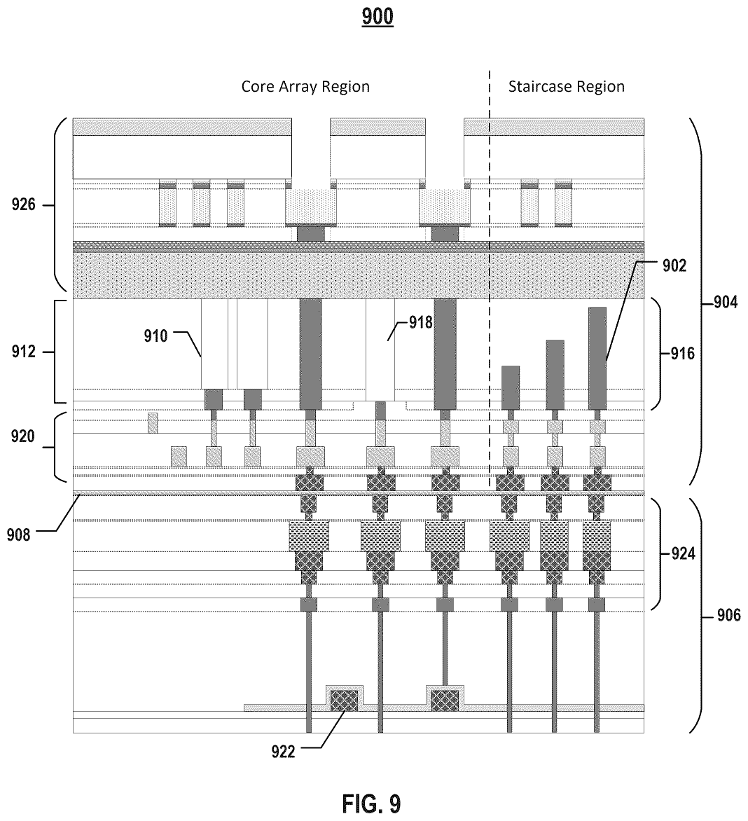

FIG. 9 illustrates an exemplary 3D memory device 900 having a contact structure 902, according to some aspects of the present disclosure. 3D memory device 900 may include a first semiconductor structure 904 bonded with a second semiconductor structure 906 at a bonding interface 908. In some implementations, first semiconductor structure 904 may include channel structures 910, in a core array region, extending through a memory stack structure 912.

According to some implementations of the present disclosure, first semiconductor structure 904 may also include contact structure 902 in a staircase region. As shown in FIG. 9, each contact in contact structure 902 may penetrate a staircase stack structure 916 at different depths and can be configured to connect with one conductive layer of memory stack structure 912. The conductive layer can serve as part of a gate line of each memory cell connected with the conductive layer and part of word line extending laterally to connect with a contact in contact structure 902 for word line fan-out. In some examples, first semiconductor structure 904 may further include an array common source (ACS) structure 918, one or more first interconnection layers 920, and a pad structure 926.

In some implementations, second semiconductor structure 906 may include one or more peripheral circuits. The one or more peripheral circuits can include a plurality of transistors 922 configured to control/manage the operations of 3D memory device 900. In some implementations, second semiconductor structure 906 may include one or more second interconnection layers 924 coupled with one or more first interconnection layers 920 through bonding interface 908.

It is apparent that FIG. 9 solely provides an exemplary memory device depicting limited components for simplification of the illustrations; it is not provided to limit the scope of the present disclosure.

Through some implementations provided by the present disclosure, contact structure 902 can be formed in contact openings after an isotropic etching to create the contact openings each having less roughness. With the isotropic etching, the etch rates can be equal in all orientations. Consequently, the roughness of the bottom surface of contact opening 102 can be substantially reduced, facilitating the subsequent formation of contact structure 902. The proposed method enhances the interface quality, leading to improved continuity at the interface for the contact material growth. As a result, the contact resistance can be reduced. The discontinuous interface between conductive layer 318 and contact structure 902 can be eliminated. As a result, an abnormal contact resistance issue can be avoided.

While the above examples describe the applications of method 200 of the present disclosure to the word line fan-out in a memory device, it can be understood that the proposed solutions can be adapted to various scenarios in metal connections in a memory device, such as a bit-line connection. The present disclosure does not limit thereto.

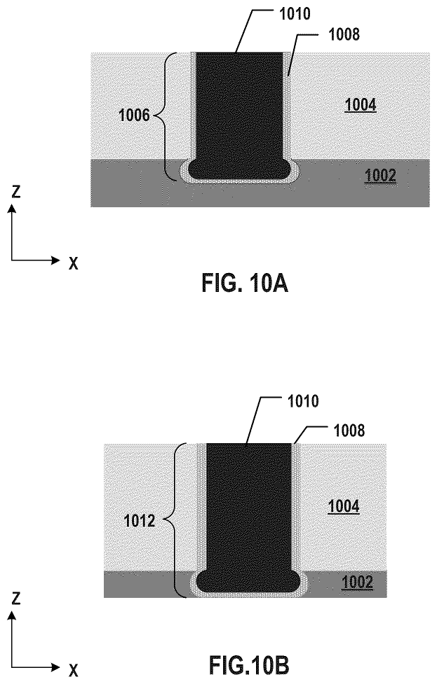

For instance, FIG. 2B illustrates another exemplary method 201 for bringing a connection between two conductor members in a memory device, according to some aspects of the present disclosure. FIGS. 10A and 10B illustrate various exemplary connections between two conductor members, according to some aspects of the present disclosure. Details of method 201 will be described with reference to FIGS. 10A and 10B.

Method 201 may start at operation 203, in which a first conductor member 1002, extending laterally, in the x-direction, may be formed, as shown in FIG. 10A. In some examples, first conductor member 1002 can be a word line as described above or a suitable conductor structure (e.g., a bit line) in a memory device, according to some implementations. First conductor member 1002 can be formed by thin film deposition processes, such as CVD, ALD, any other suitable process, or any combination thereof. In some implementations, first conductor member 1002 can include one or more conductive materials including, but not limited to, tungsten (W), cobalt (Co), copper (Cu), aluminum (Al), titanium nitride (TiN), polycrystalline silicon (polysilicon), doped silicon, silicides, or any combination thereof.

Method 201 may proceed to operation 205. At operation 205, a first opening extending, in the z-direction, through a semiconductor structure 1004 into first conductor member 1002 may be formed. Although not shown in FIG. 10A, the first opening may have a rough bottom surface, as shown in FIGS. 4A and 4B. Semiconductor structure 1004 can be staircase stack structure 308 including a conductive layer extending from memory stack structure 304, according to some implementations. In other examples, semiconductor structure 1004 can include one or more dielectric layers and/or one or more interconnection layers. In some implementations, the fabrication processes for forming the first opening may include wet etching and/or dry etching, such as deep-ion reactive etching (DRIE).

Subsequently, at operation 207, to reduce the roughness, an isotropic etching can be performed at the bottom (e.g., on the bottom surface) of the first opening to laterally expand the bottom of the first opening to form a second opening. The second opening can include a lateral recess in first conductor member 1002. Although not shown in FIG. 10A, in some examples, the second opening can include configuration/profile according to FIGS. 5-6B and include an undercut edge having a curve. In some implementations, the isotropic etching may include wet etching and/or dry etching using an etchant according to formulas (1) and (2) for a period of time between 150 seconds and 500 seconds. Details can be referred to in the description with respect to FIGS. 5-6B.

Method 201 may proceed to operation 209. At operation 209, a second conductor member 1006 can be formed. Second conductor member 1006 can include a first conductor layer 1008 arranged over the sidewalls and bottoms of the second opening including the lateral recess (e.g., the undercut). Subsequently, a second conductor layer 1010 can be formed to fill the second opening, as shown in FIG. 10A. First and second conductor layers 1008 and 1010 can be respectively formed by one or more thin film deposition processes including, but not limited to, chemical vapor deposition (CVD), physical vapor deposition (PVD), atomic layer deposition (ALD), or any combination thereof.

In FIG. 10A, first conductor member 1002 remains at the bottom of second conductor member 1006. FIG. 10B illustrates another connection manner between first conductor member 1002 and another second conductor member 1012 having first conductor layer 1008 and second conductor layer 1010. As shown in FIG. 10B, the bottom surface of second conductor member 1012 can be flush with the bottom surface of first conductor member 1002.

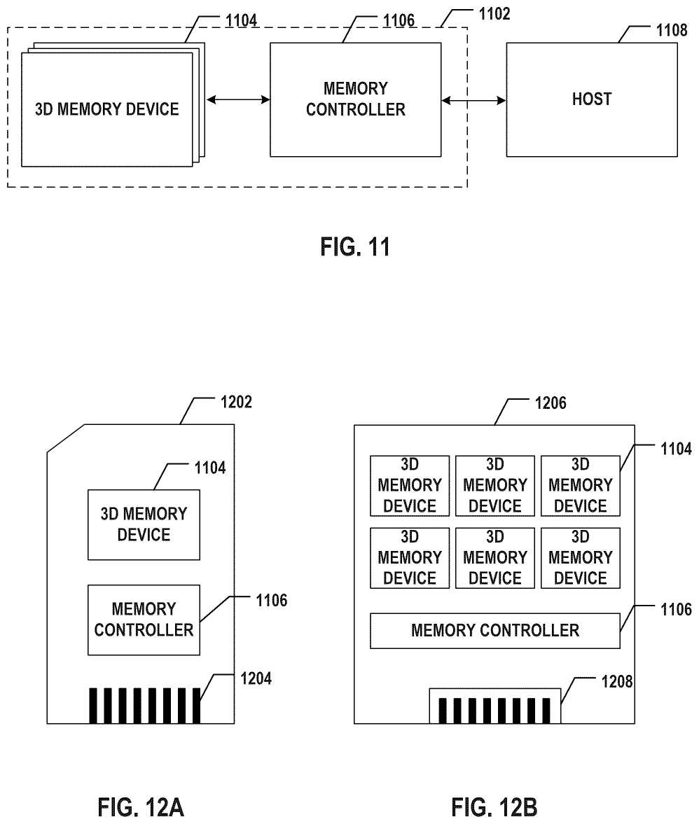

FIG. 11 illustrates a block diagram of an example system 1100 having a 3D memory device, according to some aspects of the present disclosure. System 1100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 11, system 1100 can include a host 1108 and a memory system 1102 having one or more 3D memory devices 1104 and a memory controller 1106. Host 1108 can be a processor of an electronic device, such as a central processing unit (CPU), or a system-on-chip (SoC), such as an application processor (AP). Host 1108 can be configured to send or receive data to or from 3D memory devices 1104. 3D memory device 1104 can be any 3D memory device disclosed herein, such as 3D memory device 900 depicted in FIG. 9.

Memory controller 1106 (a.k.a., a controller circuit) is coupled to 3D memory device 1104 and host 1108 and is configured to control 3D memory device 1104, according to some implementations. For instance, memory controller 1106 may be configured to operate the plurality of channel structures via the word lines. Memory controller 1106 can manage the data stored in 3D memory device 1104 and communicate with host 1108. In some implementations, memory controller 1106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1106 can be configured to control operations of 3D memory device 1104, such as read, erase, and program operations. Memory controller 1106 can also be configured to manage various functions with respect to the data stored or to be stored in 3D memory device 1104 including, but not limited to bad-block management, garbage collection, logical-to-physical address conversion, wear leveling, etc. In some implementations, memory controller 1106 is further configured to process error correction codes (ECCs) with respect to the data read from or written to 3D memory device 1104. Any other suitable functions may be performed by memory controller 1106 as well, for example, formatting 3D memory device 1104. Memory controller 1106 can communicate with an external device (e.g., host 1108) according to a particular communication protocol. For instance, memory controller 1106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1106 and one or more 3D memory devices 1104 can be integrated into diverse types of storage devices, for example, be included in the same package, such as a universal Flash storage (UFS) package or an eMMC package. That is, memory system 1102 can be implemented and packaged into several types of end electronic products. In one example as shown in FIG. 12A, memory controller 1106 and a single 3D memory device 1104 may be integrated into a memory card 1202. Memory card 1202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1202 can further include a memory card connector 1204 electrically coupling memory card 1202 with a host (e.g., host 1108 in FIG. 11). In another example as shown in FIG. 11B, memory controller 1106 and multiple 3D memory devices 1104 may be integrated into an SSD 1206. SSD 1206 can further include an SSD connector 1208 electrically coupling SSD 1206 with a host (e.g., host 1108 in FIG. 11). In some implementations, the storage capacity and/or the operation speed of SSD 1206 is greater than those of memory card 1202.

The foregoing description of the specific implementations will so reveal the general nature of the present disclosure that others can, by applying knowledge within the skill of the art, readily modify and/or adapt for various applications such specific implementations, without undue experimentation, without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all exemplary implementations of the present disclosure as contemplated by the inventor(s), and thus, are not intended to limit the present disclosure and the appended claims in any way.

The breadth and scope of the present disclosure should not be limited by any of the above-described exemplary implementations, but should be defined only in accordance with the following claims and their equivalents.

What is claimed is:

1. A semiconductor structure, comprising:
a first conductor member extending laterally in a first direction; and
a second conductor member extending in a second direction, perpendicular to the first direction, into the first conductor member,
wherein:
a first portion of the second conductor member is embedded in the first conductor member; and
in the first direction, a size of the first portion of the second conductor member embedded in the first conductor member is greater than a size of a second portion of the second conductor member outside the first conductor member.

2. The semiconductor structure of claim 1, wherein:
the first conductor member comprises an undercut edge configured to receive the first portion of the second conductor member to be in the first conductor member.

3. The semiconductor structure of claim 1, wherein:
in the first direction, a difference between a furthest edge of the first portion of the second conductor member and a furthest edge of the second portion of the second conductor member is greater than 0 and less than or equal to approximately 80 nm.

4. The semiconductor structure of claim 1, wherein:
a bottom surface of the first portion of the second conductor member is flush with a bottom surface of the first conductor member.

5. The semiconductor structure of claim 1, wherein:
a material of the first conductor member is different from a material of the second conductor member.

6. The semiconductor structure of claim 1, wherein:
the first conductor member is a layer positioned in a plane defined by the first direction and a third direction perpendicular to the first direction; and
the second conductor member is a connection structure extending in the second direction, the connection structure being configured to have an electrical connection with the layer.

7. A memory device, comprising:
a memory array structure;
a staircase structure adjacent to the memory array structure and comprising a plurality of stairs extending in a first direction; and
a contact extending, in a second direction perpendicular to the first direction, through the staircase structure into a conductive layer of one stair of the plurality of stairs in the staircase structure,
wherein:
a first portion of the contact is embedded in the conductive layer; and
in the first direction, a size of the first portion of the contact embedded in the conductive layer is greater than a size of a second portion of the contact outside the conductive layer.

8. The memory device of claim 7, wherein the contact comprises:
a glue layer in contact with the conductive layer; and
a conductor layer surrounded by the glue layer and comprising one or more conductive materials.

9. The memory device of claim 7, wherein:
the conductive layer comprises an undercut edge configured to receive the first portion of the contact in the conductive layer.

10. The memory device of claim 7, wherein:
a ratio of a depth of the first portion of the contact into the conductive layer to a thickness of the conductive layer, in the second direction, is between 0.3 and 1.

11. The memory device of claim 7, wherein:
a depth of the first portion of the contact into the conductive layer is equal to a thickness of the conductive layer, in the second direction.

12. A method for forming a semiconductor device, comprising:
forming a first conductor member extending laterally in a first direction; and
forming a second conductor member extending in a second direction, perpendicular to the first direction, into the first conductor member,
wherein:
a first portion of the second conductor member is embedded in the first conductor member; and
in the first direction, a size of the first portion of the second conductor member embedded in the first conductor member is greater than a size of a second portion of the second conductor member outside the first conductor member.

13. The method of claim 12, wherein:
forming the second conductor member extending in the second direction, comprises:
forming a first opening extending, in the second direction, through a semiconductor structure into the first conductor member, a bottom surface of the first opening comprising a first roughness;
performing an isotropic etching on the bottom surface of the first opening to form a second opening having a lateral recess in the first conductor member,
wherein:
a bottom surface of the second opening comprises a second roughness, the second roughness being less than the first roughness; and
the lateral recess of the second opening comprises an undercut edge in the first conductor member; and
forming the second conductor member in the second opening.

14. The method of claim 13, wherein:
in the second direction, the bottom surface of the second opening comprises peaks and valleys with respect to a mean value of the peaks and valleys; and
a difference between a highest peak and a lowest valley of the peaks and valleys is less than 3 nm.

15. The method of claim 13, wherein:
forming the second conductor member comprises:
forming a first conductor layer over sidewalls and the bottom surface of the second opening; and
forming a second conductor layer to fill the second opening.

16. The method of claim 13, wherein:
performing the isotropic etching comprises:
performing an isotropic etching, using an etchant, on the bottom surface of the first opening for a time.

17. The method of claim 16, wherein:
the etchant comprises a mixture of a phosphoric acid (H₃PO₄), a nitric acid (HNO₃), an acetic acid (CH₃COOH), and a water (H₂O).

18. The method of claim 17, wherein:
ratios of the phosphoric acid (H₃PO₄), the nitric acid (HNO₃), the acetic acid (CH₃COOH), and the water (H₂O) are:
H₃PO₄:HNO₃:CH₃COOH:H₂O=(0˜0.71]:(0˜0.005]:(0˜0.145]:(0˜0.12],
where (value1˜value2] represents a value greater than value 1 and less than or equal to value2.

19. The method of claim 16, wherein:
the time is between 150 seconds and 500 seconds.

20. The method of claim 13, wherein:
the semiconductor device is a three-dimensional (3D) memory device;
the semiconductor structure is a staircase structure, and the second conductor member is a contact extending, in the second direction, through the staircase structure; and
the method further comprises, before forming the contact, forming channel structures extending through a memory stack structure comprising interleaved conductive layers and dielectric layers, the first conductor member comprising an extension of a conductive layer of the conductive layers in the memory stack structure.
